(19) United States
(12) Patent Application Publication
(10) Pub. No.: US 2026/0344297 A1
(43) Pub. Date: Oct. 29, 2026

(54) Dielectric enhancement of superconductivity with metal organic framework materials

(71) Applicants: Krzysztof Kempa, Chestnut Hill, MA (US); Michael J. Naughton, Roslindale, MA (US)

(72) Inventors: Krzysztof Kempa, Chestnut Hill, MA (US); Michael J. Naughton, Roslindale, MA (US)

(73) Assignee: BOSTON COLLEGE, Chestnut Hill, MA (US)

(21) Appl. No.: 19/429,234

(22) Filed: Dec. 22, 2025

Related U.S. Application Data
(60) Provisional application No. 63/736,916, filed on Dec. 20, 2024.

(51) Int. Cl. H10N 60/80; H10N 60/01; H10N 60/12

(52) U.S. Cl. CPC H10N 60/805; H10N 60/0912; H10N 60/12

(57) ABSTRACT

Provided herein are superlattice systems containing a superconductor and a metal-organic framework medium proximity-coupled to the superconductor. These interface systems provide a resonant anti-shield (RAS) effect that significantly enhances superconductivity in certain materials. By forming these interface systems, which are sometimes referred to herein as RAS-enhanced superconductors, the critical temperature T_{c} of the superconductor material can be improved by a factor of at least 2, but possibly up to a factor of 10 or higher. Thus, the RAS-enhanced superconductors described herein may achieve superconductivity at ambient conditions (i.e., room temperature and pressure). Methods of enhancing the superconductivity performance of a superconducting material by providing a RAS effect are also described herein.

### CROSS-REFERENCE TO RELATED APPLICATIONS

This application the benefit of and priority to U.S. Provisional Patent Application No. 63/736,916, filed on Dec. 20, 2024 and titled “Dielectric Enhancement of Superconductivity with Metal Organic Framework Materials”, the contents of which are hereby incorporated by reference in their entirety.

### FIELD OF THE DISCLOSURE

The present disclosure relates generally to superconductors, and more specifically to improving superconductivity through novel engineered dielectric environments.

### BACKGROUND

Superconductivity is the property of certain materials to conduct electricity without energy loss when cools below a critical temperature (T_{c}). In typical electrical conductors, moving electrons scatter off lattice vibrations (phonons) and impurities, which cause resistance. However, in a superconductor below its T_{c}, pairs of electrons with opposite spin and momentum form Cooper pairs, which move coherently without scattering causing electrical resistivity to drop.

Practical use of superconductors has the potential to revolutionize the world's energy landscape, significant reductions in energy use and changes to renewable energy distribution. Superconductors also have the potential to complete transform other sectors of industry, such as transportation, medical imaging, computing, and energy storage, among many others. However, superconducting materials currently have no practical roles because they require cryogenic temperatures. Even 50 years after it was proposed that superconductivity at room temperature was theoretically possible for certain materials, the superconductivity record achieved in the cuprates in 1993 still holds, at a transition temperature T_{c}~133 K. Overall, both theoretical and practical progress in superconductivity has been limited.

### SUMMARY OF THE DISCLOSURE

Provided herein are interface systems containing a superconductor and a metal-organic framework medium proximity-coupled, or interfaced, to the superconductor. These interface systems provide a resonant anti-shield (RAS) effect wherein the nonlocal dielectric function of the environment vanishes, thereby significantly enhancing superconductivity in certain materials. The RAS effect is universal, since it relies on the fact that Cooper pairs, regardless of the pairing mechanism, are simply charges that can be affected by external charges/fields induced in an engineered dielectric environment. By forming these interface systems, which are sometimes referred to herein as RAS-enhanced superconductors, the critical temperature T_{c} of the superconductor material can be improved by a factor of at least 2, but possibly up to a factor of 10 or higher. Thus, the RAS-enhanced superconductors described herein may achieve superconductivity at ambient conditions (i.e., room temperature and pressure). Methods of enhancing the superconductivity performance of a superconducting material by providing a RAS effect are also described herein.

According to an embodiment of the present disclosure, a resonant anti-shielding (RAS)-enhanced superconductor is disclosed. The RAS-enhanced superconductor can include a stacked arrangement of: (i) at least one superconducting layer formed from a superconducting material, and (ii) one or more dielectric layers formed from a point-dipole crystal or metal-organic framework material. The point-dipole crystal or metal-organic framework material can include a plurality of polarizable units. The point-dipole crystal or metal-organic framework material can form a crystal lattice with a unit cell having a lattice period d, and each of the one or more dielectric layers can have a thickness a. The superconducting material can have a superconducting coherence length (ξ). In preferred embodiments, the thickness a of each of the one or more dielectric layers is no greater than the lattice period d of the point-dipole crystal or metal-organic framework material, and the superconducting coherence length (ξ) of the superconducting material is at least 3 times the lattice period d of the point-dipole crystal or metal-organic framework material.

In an aspect, the one or more dielectric layers are formed from a metal-organic framework material and the plurality of polarizable units can be periodically distributed in an organic matrix.

In an aspect, the organic matrix of the metal-organic framework material can be planar/two-dimensional.

In an aspect, the crystal lattice formed from the point-dipole crystal or metal-organic framework can have a two-dimensional and/or square configuration.

In an aspect, the point-dipole crystal or metal-organic framework material can have a resonance peak at a frequency ω that coincides in frequency space with a peak or peaks in the Eliashberg function of the superconducting material.

In an aspect, the point-dipole crystal or metal-organic framework material can have a dielectric function that is q-independent, i.e., ε_{MOF}(ω, q)=ε_{MOF}(ω).

In an aspect, the plurality of polarizable units of the point-dipole crystal or metal-organic framework material can have phonon modes that are highly localized.

In an aspect, each polarizable unit of the plurality of polarizable units can have a size a and a q on the order of 1/a>>k_{f}.

In an aspect, the stacked arrangement can include alternating layers of the superconducting layer formed from the superconducting material and one of the one or more dielectric layers formed from the point-dipole crystal or metal-organic framework material.

In an aspect, the lattice period d of the point-dipole crystal or metal-organic framework material is about 0.35 nm.

In an aspect, the superconducting material has an effective thickness D of about 0.35 nm.

In an aspect, the stacked arrangement of the at least one superconducting layer and the one or more dielectric layers can be characterized by an effective dielectric function ε_{DE}(ω) given approximately by the equation:

ε_{DE}(ω)=(1−f)+fε_{MOF}(ω)

where ε_{MOF}(ω) is a q-independent dielectric function characterizing each of the one or more dielectric layers, and f is a filling parameter defined by:

$$f = \frac{d}{D + d}$$

where D is an effective thickness of each layer of the at least one superconducting layer, and d is the lattice period of the point-dipole crystal or metal-organic framework material.

In an aspect, the stacked arrangement of the at least one superconducting layer and the one or more dielectric layers is further characterized by an immersion relationship given approximately by the equation:

D+d≤ξ

where [symbol] is the superconducting coherence length of the superconducting material.

In an aspect, the filling parameter f is at most 0.5.

In an aspect, the RAS-enhanced superconductor has a superconducting critical temperature (T_{c}) at or above ambient room temperature and pressure.

In an aspect, the RAS-enhanced superconductor has a superconducting critical temperature (T_{c}) that is at least four times (4×) a superconducting critical temperature

$$( {T}_{c}^{SC} )$$

of the superconducting material alone.

According to another embodiment of the present disclosure, a method of enhancing performance of a superconductor by providing a resonant anti-shielding (RAS) effect is disclosed. The method can include: (1) providing at least one superconducting layer formed from a superconducting material, wherein the superconducting material has a superconducting coherence length [symbol] ); (2) providing one or more dielectric layers formed from a point-dipole crystal or metal-organic framework material, wherein the point-dipole crystal or metal-organic framework material comprises a plurality of polarizable units and forms a crystal lattice with a unit cell having a lattice period d, and wherein each of the one or more dielectric layers has a thickness a; and (3) forming a stacked arrangement using the at least one superconducting layer and the one or more dielectric layers. As described, the thickness a of each of the one or more dielectric layers is no greater than the lattice period d of the point-dipole crystal or metal-organic framework material, and the superconducting coherence length ( [symbol] ) of the superconducting material is at least 3 times the lattice period d of the point-dipole crystal or metal-organic framework material.

In an aspect, the stacked arrangement of the at least one superconducting layer and the one or more dielectric layers can be characterized by an effective dielectric function ε_{DE}(ω) given approximately by the equation:

ε_{DE}(ω)=(1−f)+fε_{MOF}(ω)

where ε_{MOF}(ω) is a q-independent dielectric function characterizing each of the one or more dielectric layers, and f is a filling parameter defined by:

$$f = \frac{d}{D + d}$$

where D is an effective thickness of each layer of the at least one superconducting layer, and d is the lattice period of the point-dipole crystal or metal-organic framework material.

In an aspect, the stacked arrangement of the at least one superconducting layer and the one or more dielectric layers is further characterized by an immersion relationship given approximately by the equation:

D+d≤ξ

where [symbol] is the superconducting coherence length of the superconducting material.

In an aspect, the RAS-enhanced superconductor has a superconducting critical temperature (T_{c}) at or above ambient room temperature and pressure, and/or has a superconducting critical temperature (T_{c}) that is at least four times (4×) a superconducting critical temperature

$$( {T}_{c}^{SC} )$$

of the superconducting material alone.

These and other aspects of the various embodiments will be apparent from and elucidated with reference to the embodiments described hereinafter.

### BRIEF DESCRIPTION OF THE DRAWINGS

In the drawings, like reference characters generally refer to the same parts throughout the different views. The figures showing features and ways of implementing various embodiments and are not to be construed as being limiting to other possible embodiments falling within the scope of the attached claims. Also, the drawings are not necessarily to scale, emphasis instead generally being placed upon illustrating the principles of the various embodiments.

FIG. 1 is a schematic drawing of an RAS-enhanced superconductor illustrated in accordance with aspects of the present disclosure.

FIG. 2 is a schematic drawing of another RAS-enhanced superconductor illustrated in accordance with aspects of the present disclosure.

FIG. 3 is a flowchart illustrating a method of enhancing the superconductivity performance of a material by providing an RAS effect in accordance with aspects of the present disclosure.

FIG. 4 is a schematic drawing of still another RAS-enhanced superconductor illustrated in accordance with aspects of the present disclosure.

FIG. 5 is an illustration of the structure and relative arrangement of a metal-organic framework material and a superconducting material provided in an RAS-enhanced superconductor of the present disclosure.

FIG. 6 is a graph illustrating Eliashberg function ∝² F(ω) for MgB₂.

FIG. 7 is a graph plotting the maximum enhanced critical temperature for an RAS-enhanced superconductor estimated using Leavens' method in accordance with aspects of the present disclosure.

### DETAILED DESCRIPTION OF EMBODIMENTS

According to embodiments of the present disclosure, interface systems and methods of enhancing the superconductivity of certain superconducting materials by imparting a resonant anti-shielding (RAS) effect through an engineered metal-organic framework (MOF) that is interfaced/proximity-coupled to the superconducting material. In various embodiments, the systems and methods can result in significant improvements to the critical temperature T_{c}. In some embodiments, the critical temperature T_{c} of the superconducting material may increase by at least 2×, including at least 10× or higher, without the need for the application of high pressure. Thus, in certain embodiments, the systems and methods described herein can achieve superconductivity under ambient conditions (i.e., room temperature and pressure).

The interface systems and methods of the present disclosure involve engineering an existing superconductor's dielectric environment (DE) to enhance its T_{c}. A material used in the an engineering DE can be characterized by its dielectric function, which describes how the material responds to an external electric field, particularly in terms of polarization and screening effects. In conventional systems, the dielectric function of the environment is frequency- and wavevector-dependent, thus denoted ε(ω, q). When entering the electron-electron interaction diagram (e.g., the Frohlich term) in the form |ε(ω, q)|⁻², a so-called epsilon-near-zero (ENZ) condition is observed, i.e., ε(ω, q)→0. This is associated with the resonant anti-shielding (RAS) effect.

However, achieving RAS can be challenging for a number of reasons. The corresponding ENZ condition must occur simultaneously for frequencies W in the range of the electron-electron pairing excitations (near the Eliashberg function maximum), and for very large momentum wave vector q (of the order k_{F}, the Fermi wave vector of the coupled quasiparticles), as required by the very large momentum transfer occurring during Cooper pair formation. Consequently, it is not surprising that experimental attempts to obtain RAS by employing conventional metallic metamaterials as the DE has led to only modest T_{c} enhancements.

According to aspects of the present disclosure, it was recognized that in order to impart a meaningful RAS effect to a superconductor and achieve a significant improvement in superconductivity performance (i.e., higher critical temperatures), a material used to form the dielectric environment must first have a well-defined effective ε(ω, q) (WDEE). Thus, as described herein, various dielectric materials for forming the dielectric environment surrounding a superconductor are provided that satisfy these WDEE conditions.

In embodiments, the dielectric material can consist of small, dynamically-active, polarizable elements of size a, which may be immersed in a passive matrix in some cases. The polarizable elements may be distributed throughout the matrix and have an average spacing distance d apart. As used herein, the average spacing distance d may also be referred to as the lattice period of the dielectric material. According to certain aspects of the present disclosure, the RAS-enhanced superconductor may be characterized by the following relationship:

a<d<<ξ R1

where ξ is the superconducting coherence length of the superconductor material.

In other words, according to certain aspects of the present disclosure, the dielectric material may be engineered relative to a particular superconducting material such that the size (a) of the polarizable elements of the dielectric material is less than the inter-element spacing distance (d), which is less than and/or much less than the superconducting coherence length (ξ) of the superconducting material.

In embodiments, the superconducting coherence length (ξ) may be at least about 2 times the inter-element spacing distance (d) of the dielectric material, including at least 3 times, at least about 4 times, and/or at least about 5 times the inter-element spacing distance (d) of the dielectric material.

In particular embodiments, the dielectric material forming the dielectric environment around the superconductor is a point-dipole crystal (PDC) or a metal-organic framework (MOF) material. In embodiments, the point-dipole crystal may comprise a plurality of polarizable units (i.e., polarizable elements) distributed in a periodic structure or array. In embodiments, the point-dipole crystal may possess a dielectric response function ε(ω, q) which contains one or more resonance peaks that align in wave-vector space with peaks in the Eliashberg function of an interfaced superconductor. In specific embodiments, the point-dipole crystal can be a ferroelectric or piezoelectric crystal.

In further embodiments, the metal-organic framework material comprises a plurality of polarizable units (i.e., polarizable elements) distributed in an organic matrix, which together form a crystal lattice. In embodiments, the polarizable units may be periodically/regularly distributed throughout the organic matrix. In further embodiments, the organic matrix may be a two-dimension planar matrix. In particular embodiments, the MOF material is a crystal that possesses a dielectric response function ε(ω, q) which contains one or more resonance peaks that align in wave-vector space with peaks in the Eliashberg function of an interfaced superconductor.

As mentioned above, the dielectric material can have an inter-element spacing distance (d), which may also be referred to as a lattice period (d) in the context of the MOF material or PDC. According to aspects of the present disclosure, the crystals of the dielectric material may have a square lattice structure. However, the crystals of the dielectric material may also have a different lattice structure. In embodiments, the crystals of the dielectric material can have a lattice structure such that the spacing distance (i.e., lattice period) d is greater than the crystal thickness (i.e., size of the polarizable elements) a, as indicated in the relationship R1 above.

In embodiments, the polarizable units of the PDC or the MOF material may have highly localized phonon modes. That is, the atomic size of the polarizable units of the dielectric material may be such that there is q-independent dispersion. As such, according to aspects of the present disclosure, the MOF material may have a dielectric function that is q-independent, which may be expressed as shown in Equation 1 below:

ε_{MOF}(ω,q)=ε_{MOF}(ω) Eqn. 1

According to further aspects of the present disclosure, the q-independence of the MOF material's dielectric function may also be characterized by the following relationship:

1/a>>k_{F} R2

where a is the size of the polarizable unit and k_{F} is the Fermi wave vector of the coupled quasiparticles from the superconducting material.

In other words, given the phonon modes of a polarizable unit of a particular size a, it is expected that q-independent dispersion is obtained for sufficient large q's. As noted above, the wave vector q relates the wavelength of an vibrational excitation and is correlated with the momentum of the excitation. For crystals with large q's, more localized vibrations are seen, whereas for crystals with small q's, more uniform vibrations occur across the crystal are seen. In embodiments of the present disclosure, the dielectric materials can have large q's on the order of R2.

In particular embodiments, the localization phonon modes is further enhanced by very little coupling of these modes to the organic matrix, which may be observed in the Raman spectra for the MOF material. For example, in particular embodiments, the Raman spectra for the MOF material will exhibit peaks corresponding to different vibrational modes (i.e., phonons) of the MOF material. It will be appreciated by those of skill in the art that collective oscillations of the MOF material are expressed as discrete energy units called phonons. Thus, these peaks correspond to an excitation energy E of a phonon, which may be expressed as shown in Equation 2 below:

E=ℏω Eqn. 2

where E is the excitation energy of a phonon, ω is the angular frequency of the lattice vibration, and ℏ is the reduced Planck's constant.

In preferred embodiments, the Raman spectra for the PDC or MOF material will exhibit one or more resonance peaks associated with the polarizable unit(s) at particular angular frequencies ω (i.e., excitation energies) or within a particular range of such angular frequencies ω, that coincide in frequency space with a peak or peaks in the Eliashberg function of the interfaced superconductor. In embodiments, the resonance peaks associated with the polarizable units and/or the coincidental peaks in the Eliashberg function of the interface superconductor may not be required to be sharp in order for mode locking to occur and be effective. That is, mode locking can still occur and be effective even with a low amplitude or broader local maximum.

Thus, according to particular aspects of the present disclosure, the MOF materials described herein can be characterized by an effective dielectric function at the desired resonance peak, which may be expressed as shown in Equation 3 below:

$${ε}_{MOF} ( ω , q ) = {ε}_{MOF} ( ω ) = \frac{{ω}_{LO}^{2} - ω ( ω + i γ )}{{ω}_{TO}^{2} = ω ( ω + i γ )} \qquad Eqn . 3$$

where ω_{LO} and ω_{TO} are characteristic frequencies associated with transverse optical and longitudinal optical phonon modes, respectively, and γ is a loss factor.

In particular embodiments, the ENZ condition of the MOF material (i.e., ε_{MOF}(ω, q)≈0) can occur at the value ω_{LO} included in Eqn. 3 above, which may be near or very near the maximum of the Eliashberg function ∝² F(ω) for the superconducting material. In such embodiments, it is believed that the RAS effect will be improved and/or maximized.

It will be appreciated by those of skill in the art that there may be additional resonances near the ω_{TO} resonance of interest in the MOF Raman spectra, which result mostly from phonon activity in the organic matrix. The additional phonon activity of these polarization terms may be accounted for using the general field-theoretical analysis described in D. van der Marel, “Optical spectroscopy of plasmons and excitons in cuprate superconductors”, J. Supercon. 17, 559-575 (2004). Doi: 10.1007/s10948-004-0770-3. For example, a hydrodynamic form for the q-dependence of the other polarization terms by be expressed as shown in Equation 4 below:

$${π}_{ot} ( ω , q ) = {\sum }_{n = 1}^{M} \frac{{ω}_{p}^{2}}{{ω}_{n}^{2} + β {q}^{2} - ω ( ω + i {γ}_{n} )} \qquad Eqn . 4$$

If the other polarization terms are due to the typical dispersive phonon modes, this results in contributions that are vanishing for the MOF materials at the required very large q's. This relationship may be characterized as shown below:

πₒₜ(ω_{TO},q)<<1 R3

Thus, as an unexpected benefit of the required large q's, the effective dielectric function of the MOF material ε_{MOF}(ω, q) becomes dominated by the resonance at ω_{TO}.

According to aspects of the present disclosure, various structures/arrangements of superconducting materials and dielectric materials providing a resonant anti-shielding (RAS) effect are described. In embodiments, these RAS-enhanced superconductors can include at least one layer formed from a crystalline superconducting material, and one or more metal-organic framework (MOF) layers formed from a MOF material. As described, the superconductor layers and the MOF layers are proximity-coupled, meaning the layers form a stacked arrangement in close proximity with one another. In particular embodiments, the superconductor layers and the MOF layers are in direct contact with each other, i.e., the layers make face-to-face contact. In particular embodiments, the interface between the superconductor and the PDC or MOF can be epitaxial in nature, i.e., where one crystal is grown on top of the other. In other embodiments, deposition of a film of one material on the other (in either order) may be performed through, e.g., physical vapor deposition, chemical vapor deposition, atomic layer deposition, and/or similar processes. In embodiments, the layers need not be specially bonded to each other.

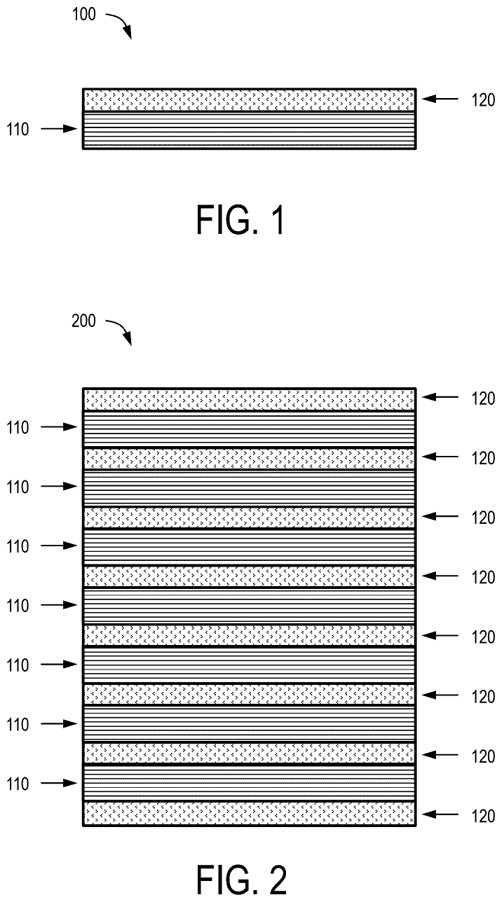

For example, with reference to FIG. 1 and FIG. 2, cross-sectional side views of embodiments of an RAS-enhanced superconductor are illustrated in accordance with certain aspects of the present disclosure. As shown in FIG. 1, one embodiment of an RAS-enhanced superconductor 100 is illustrated, which includes a superconducting layer 110 formed from a superconducting material and a dielectric layer 120 formed from a PDC or MOF material. According to this embodiment, the interface between the superconducting layer 110 and the DPC or MOF layer 120 imparts a RAS effect to the superconducting material layer 110.

With reference to FIG. 2, the general embodiment from FIG. 1 is expanded to an RAS-enhanced superconductor 200 consisting of a superlattice of unit cell-thick dielectric layers 120 and superconducting material layers 110. The specific number of each of the layers 110, 1200 is not particularly limited, except that the layers 110, 120 are proximity-coupled and/or form a stacked arrangement as shown. Thus, in particular embodiments, the RAS-enhanced superconductor 200 may include two or more superconducting layers 110, including a plurality of superconducting layers 110. In further embodiments, the RAS-enhanced superconductor 200 may similarly include a plurality of PDC/MOF layers 120. In embodiments, the PDC/MOF layers 120 may be uniformly distributed as part of the RAS-enhanced superconductor 200.

As described herein, the superconducting layer(s) 110 of the RAS-enhanced superconductors 100, 200 may be effectively immersed in the dielectric environment (DE) formed by the dielectric layers 120. In particular, the stacked arrangement of the layers 110, 120 may be characterized by an effective dielectric function ε_{DE}(ω) given approximately by Equation 5 below:

ε_{DE}(ω)=(1−f)+fε_{MOF}(ω) Eqn. 5

where ε_{MOF}(ω) is a q-independent dielectric function characterizing each of the one or more PDC/MOF layers 120, and f is a filling parameter defined by Equation 6 below:

$$f = \frac{d}{D + d} \qquad Eqn . 6$$

where D is an effective thickness of each layer of the at least one superconducting layer, and d is the lattice period of the PDC/MOF material forming the dielectric layers 120.

Notably, the filling parameter f assumes that the dielectric function of the superconductor itself is 1, which is expected for very large q's.

In further embodiments, the stacked arrangement of the layers 110, 120 in the RAS-enhanced superconductor 100, 200 may be characterized by an immersion relationship given by the following relationship:

D+d≤ξ R4

where ξ is the superconducting coherence length of the crystalline superconducting material used to form the superconducting layer(s) 110.

Based on these equations and relationships, it will be appreciated that for a fixed d, the filling parameter f increases monotonically with decreasing D, which in turn cannot be thinner than a single atomic monolayer of the superconducting material. Thus, it will also be appreciated by those of skill in the art that there will a minimum thickness (Dₘᵢₙ) for the superconducting layers 110 that limits the thickness/lattice period d of the dielectric layers 120 such that Cooper pair coherence can still extend throughout large sections of the RAS-enhanced superconductor 100, 200. In particular embodiments, the relationship between these features may be characterized according to the following relationship:

Dₘᵢₙ+d<<ξ R5

This relationship, in turn, means that there is a maximum value for the filling parameter, i.e., fₘₐₓ, based on Dₘᵢₙ. Put in other terms, the RAS-enhanced superconductors 100, 200 of the present disclosure may be characterized by a filling parameter f as described above, wherein f is less than fₘₐₓ. In embodiments, fₘₐₓ may be, for example and without limitation, 0.5.

According to aspects of the present disclosure, the RAS-enhanced superconductors 100, 200 advantageously exhibit improved superconductivity performance, namely, a higher critical temperature T_{c} when compared to the same superconductor without the engineering dielectric environment (DE). In other words, by providing an effective RAS effect to the superconducting material as described herein, the superconducting critical temperature can be meaningfully increased. In embodiments, the RAS-enhanced superconductor 100, 200 has an enhanced superconducting critical temperature T′_{c} at or above ambient room temperature and pressure. In further embodiments, the enhanced superconducting critical temperature T′_{c} is at least two times (2×) the critical temperature T_{c} of the superconductor material alone, including at least three times (3×), at least four times (4×), and/or at least five times (5×) the critical temperature T_{c} of the superconductor material alone. In still further embodiments, the enhanced superconducting critical temperature T′_{c} may be about ten times (10×) the critical temperature T_{c} of the superconductor material alone.

Accordingly, provided herein are superlattice systems 100, 200 containing a superconductor 110 and a metal-organic framework medium 120 proximity-coupled to the superconductor 110. These interface systems 100, 200 provide a resonant anti-shield (RAS) effect wherein the nonlocal dielectric function of the environment vanishes, thereby significantly enhancing superconductivity (i.e., critical temperatures T_{c}) in certain materials. The RAS effect is universal since it relies on the fact that Cooper pairs, regardless of the pairing mechanism, are simply charges that can be affected by external charges/fields induced in an engineered dielectric environment. By forming these interface systems 100, 200, which are sometimes referred to herein as RAS-enhanced superconductors, the critical temperature T_{c} of the superconductor material can be improved by a factor of at least 2, but possibly up to a factor of 10 or higher. Thus, the RAS-enhanced superconductors described herein may achieve superconductivity at ambient conditions (i.e., room temperature and pressure).

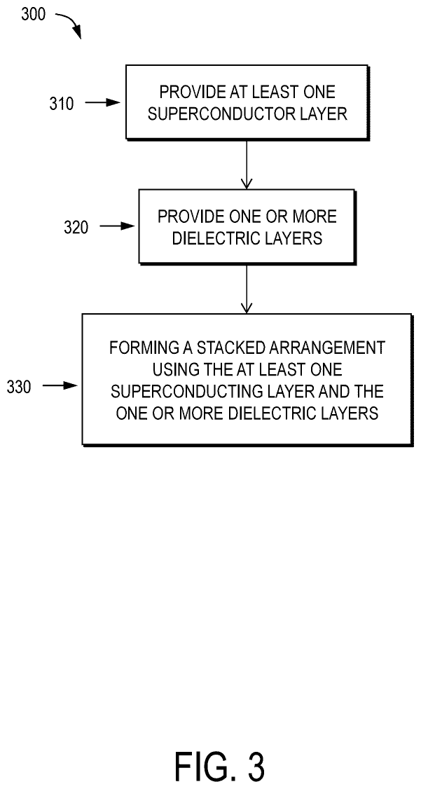

Also provided herein are methods of enhancing the superconductivity performance of a superconducting material by providing a RAS effect are also described herein. For example, with reference to FIG. 3, a flowchart illustrating a method 300 of enhancing performance of a superconductor by providing a resonant anti-shielding (RAS) effect is illustrated according to aspects of the present disclosure.

As shown, the method 300 can include, in a step 310, providing at least one superconducting layer 110 formed from a superconducting material, wherein the superconducting material has a superconducting coherence length (ξ). In embodiments, each superconducting layer 110 may be an ultrathin film. This superconducting layer can be a crystalline film cleaved or exfoliated from a bulk crystal, or a film deposited onto a substrate via a chemical vapor deposition (CVD), physical vapor deposition (PVD), or a similar method.

Examples of substrates include silicon, silicon carbide, silicon nitride, silicon oxide, gallium arsenide, strontium titanate, and numerous other known electrically insulating or semiconducting materials. Examples of CVD methods include thermal CVD, plasma-enhanced CVD, atomic layer deposition, molecular layer deposition, and molecular beam epitaxy, and examples of PVD methods include thermal evaporation, electron beam evaporation, magnetron sputtering, and pulsed laser deposition.

In a step 320, the method 300 can include providing one or more dielectric material layers 120, namely, one or more PDC layers formed from point-dipole crystals and/or one or more MOF layers formed from a metal-organic framework material. In embodiments, each dielectric layer 120 may be a single unit thick crystal, but may also be a stack of multiple single unit thick crystals, or microcrystalline, nanocrystalline, or amorphous materials. In preferred embodiments, the material forming the dielectric layers 120 comprises a plurality of polarizable units distributed in a period structure or lattice, e.g., forming a crystal lattice with a unit cell having a lattice period d, and wherein each of the one or more dielectric layers 120 has a thickness a.

In a step 330, the method 300 can then include forming a stacked arrangement using the at least one superconducting layer 110 and the one or more metal-organic framework layers 120. MOF layers can be variously deposited by the aforementioned CVD and PVD methods. In embodiments, this may include coupling the superconductor layers 110 and the dielectric layers 120, i.e., forming proximity-coupled layers 110, 120, meaning the layers 110, 120 form a stacked arrangement in close proximity with one another. In particular embodiments, the superconductor layers 110 and the dielectric layers 120 are in direct contact with each other, i.e., the layers make face-to-face contact.

As mentioned above, the interface between the superconductor layer(s) 110 and the PDC or MOF layer(s) 120 can be epitaxial in nature, i.e., where one crystal is grown on top of the other. In other embodiments, deposition of a film of one material on the other (in either order) may be performed through, e.g., physical vapor deposition, chemical vapor deposition, atomic layer deposition, and/or similar processes. In embodiments, the layers 110, 120 need not be specially bonded to each other.

In particular embodiments, the thickness a of each of the one or more metal-organic framework layers 120 is no greater than the lattice period d of the metal-organic framework material, and the superconducting coherence length (ξ) of the crystalline superconducting material is at least 3 times the lattice period d of the metal-organic framework material.

In further embodiments, the stacked arrangement of the at least one superconducting layer 110 and the one or more dielectric layers 120 is characterized by an effective dielectric function ε_{DE}(ω) given approximately by Equation 5 above.

In still further embodiments, the stacked arrangement of the at least one superconducting layer 110 and the one or more dielectric layers 120 formed in the step 330 may be further characterized by an immersion relationship given approximately by the relation R4 described above.

Accordingly, forming superlattice systems 100, 200 as described herein imparts a resonant anti-shield (RAS) effect that significantly enhances superconductivity (i.e., critical temperatures T_{c}) in certain materials, including by improving the critical temperatures T_{c} by a factor of at least 2, but possibly up to a factor of 10 or higher. In particular embodiments, the RAS-enhanced superconductors 110, 200 described herein may achieve superconductivity at or above ambient conditions (i.e., room temperature and pressure).

### Examples

As described herein, this disclosure presents multiple aspects that are further illustrated by the following non-limiting examples.

MgB₂—Mo₂(INA)₄ Superlattice Arrangement

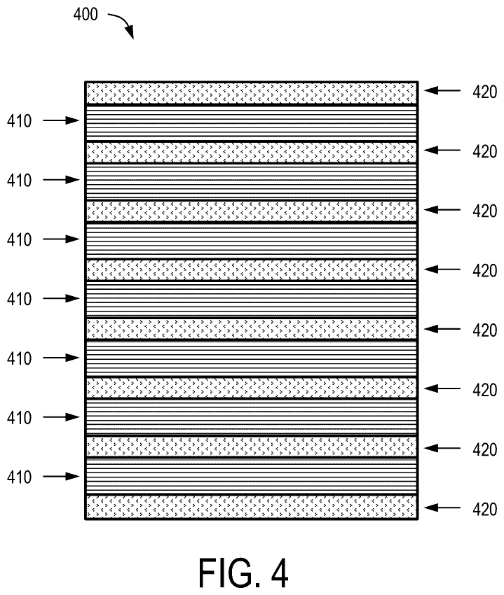

According to the present disclosure, an RAS-enhanced superconductor (i.e., an interface arrangement) may be formed using magnesium diboride (MgB₂) as the superconductor material and Mo₂(INA)₄ as the metal-organic framework (MOF) material. As shown in FIG. 4, a superlattice interface arrangement 400 is illustrated that comprises a plurality of MOF film layers 420 that sandwich film layers 410 of a superconducting material. In embodiments, each layer 410, 420 can be one unit cell, many unit cells, or even a thin non-crystalline film. In particular embodiments, MOF film layers 420 comprise a plurality of unit cells 420 of the MOF crystal material, which sandwich a plurality of unit cells 410 of an MgB₂ crystal.

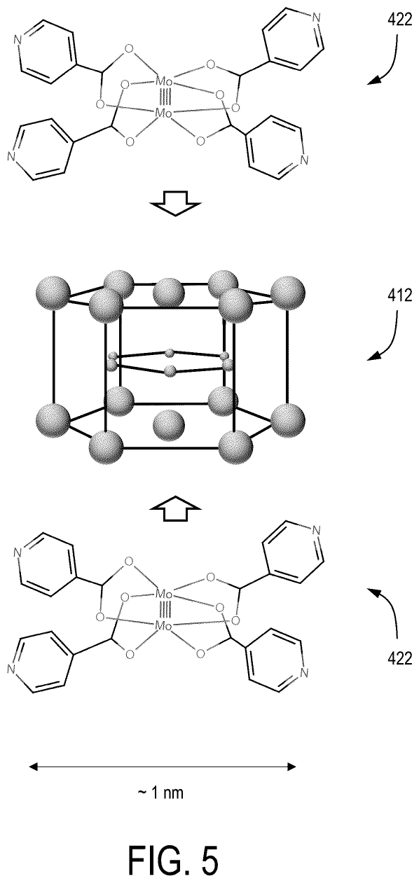

Regarding the superconducting material, it will be appreciated by those of skill in the art that MgB₂ crystallizes in the hexagonal P6/mmm space group, and its structure contains graphite-type boron layers separated by hexagonal close-packed layers of magnesium. The Mg atoms are located at the centers of hexagons formed by B atoms, and donate their electrons to the B planes. Regarding the MOF material, it will be appreciated by those of skill in the art that Mo₂(INA)₄ forms a two-dimensional metal-organic framework having a square lattice structure, wherein a pair of quadruple-bonded Mo atoms serve as the polarizable unit, which are periodically distributed in a planar organic matrix formed by four isonicotinate ligands. In FIG. 5, a schematic of the arrangement of MgB₂ and Mo₂(INA)₄ crystals, which make up the alternating unit cell-thick layers 410, 420 from FIG. 4, is illustrated.

According to aspects of the present disclosure and with further respect to this particular embodiment, the superconducting material MgB₂ has a superconducting coherence length ξ≈7 nm, the MOF crystal thickness and the size of the polarizable unit (i.e., the pair of bonded metal atoms) is roughly a~0.3 nm, and the period of the MOF square lattice crystal is d≈1.2 nm. Accordingly, the WDEE condition is approximately satisfied for this system, as indicated by the relationship R1 described above. That is, for MgB₂ and Mo₂(INA)₄, the relationship a<d<<ξ is satisfied.

Additionally, it was experimentally confirmed that the Raman spectra of this MOF crystal shows a very sharp feature at ℏω≈45 meV, which represents highly localized phonon oscillations of the pair of Mo atoms. The frequency of this resonance peak is in the required range based on the unique Eliashberg function for MgB₂, and therefore the frequency part of the RAS condition is satisfied. The q-requirement is also simultaneously satisfied, since the corresponding dielectric function is q-independent, which is due to the fact that the phonon modes of the atomic size (≈0.3 nm) Mo oscillators are highly localized, which translates into q-independent dispersion, at least for q on an order that satisfies relationship R2. This localization is further enhanced by very little coupling of these modes to the organic matrix, as evidenced by the sharpness of the Raman peak.

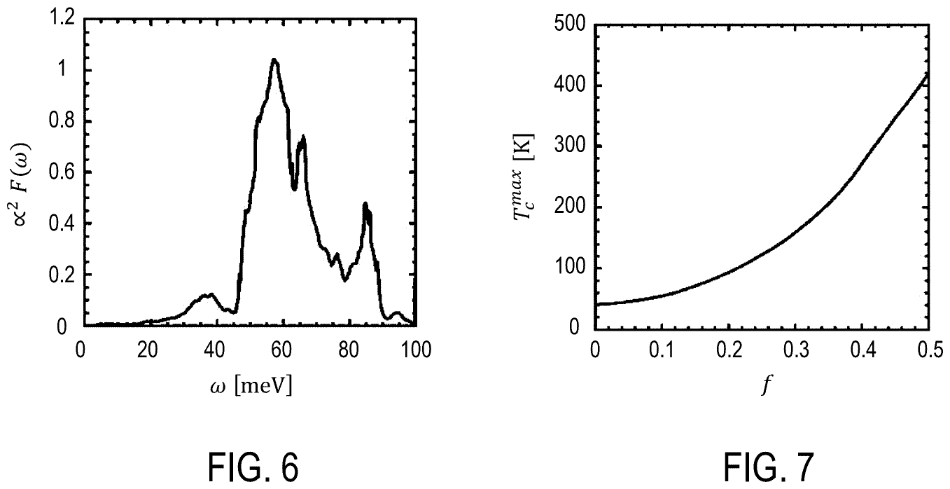

By applying Equation 3 to the Raman data for this system, θ_{TO}=45 meV and γ=1.32 meV. From experimental and simulation data on similar MOFs, it can be assumed that ε_{MOF}(0)≈2, and thus, ω_{LO}≈60 meV is determined. Notably, the ENZ condition occurs at this value of ω_{LO}, which is near the maximum of the Eliashberg function ∝² F(ω) for MgB₂ as shown in the graph of FIG. 6.

Although there are additional resonances near the ω_{TO}=45 meV resonance of interest in the MOF spectrum, these result mostly from phonon activity in the organic matrix and can be easily accounted for by using the general field-theoretical analysis of van der Marel, which leads to a simple hydrodynamic form for the q-dependence of the other polarization terms, i.e., as shown in Equation 4, where

$${ω}_{pn}^{2}$$

is the oscillator strength of the n-th term, ωₙ is the frequency of the other resonance, and γₙ is the corresponding loss factor. However, as discussed above, for the MOF at the required very large q, the relationship R3 holds true as long as these terms are due to the usual dispersive phonon modes. As such, these contributions to the large q response are vanishing and the dielectric function of the MOF is advantageously dominated by the resonance at ω_{TO}=45 meV.

According to aspects of this example, the RAS-enhanced superconductor 400 consists of a superlattice of unit cell-thick layers of MOF (d≈0.35 nm) and MgB₂ (D≈0.35 nm). Since the coherence length for MgB₂ is ξ~7 nm, coherent coupling between MgB₂ layers 410 extends well outside the perimeters of the superlattice fragment shown in FIG. 4. Thus, the MgB₂ superconductor is effectively immersed I the DE of the MOF, uniformly distributed inside the superconductor. By applying Equations 5 and 6 as well as the relationship R4, a minimum superconducting layer thickness Dₘᵢₙ≈0.35 nm is determined, from which a maximum filling parameter value fₘₐₓ=0.5 is determined. Using this maximum value, the maximum enhanced critical temperature is estimated to be approximately 420 K (which is well into the room temperature range) using Leavens' method, as shown in the graph of FIG. 7.

### Other Examples

Although one example of a superlattice arrangement comprising MgB₂ and Mo₂(INA)₄ is described, it is contemplated that other crystalline superconducting materials and metal-organic framework materials may be utilized within the bounds of the various relationships and constraints described above.

For example, and without limitation, it is specifically contemplated that the RAS-enhancements described herein can also be applied to the cuprates, such as the cuprate superconductor YBa₂Cu₃O_{7-δ} (YBCO).

In further embodiments, superconductivity performance in ultrathin FeSe films on SrTiO₃ may be similarly enhanced by providing an RAS effect, and in particular, with respect to single-unit-cell FeSe films on SrTiO3 (STO) and related substrates. This material exhibits a broad Raman spectra consisting of multiple peaks and extends from about 3 to 45 meV. In this example, the maximum enhanced critical temperature estimated for bulk FeSe was estimated to be

$${T}_{c}^{max}$$

≈5.4 K. However, the enhanced critical temperature for a single unit-cell-thick FeSe layer on three monolayers of STO was estimated to be

$${T}_{c}^{max}$$

≈77 K. Thus, as mentioned above, a very small and not so sharp peak in the Eliashberg function of the superconductor FeSe was identified as the one to match a peak in the engineering SrTiO3 substrate (i.e., the PDC), and this match resulted in a 10-fold increase in T_{c}.

### DEFINITIONS

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

All definitions, as defined and used herein, should be understood to control over dictionary definitions, definitions in documents incorporated by reference, and/or ordinary meanings of the defined terms.

As used herein in the specification and in the claims, the term “room temperature and pressure” refers to conditions approximating ambient laboratory environment, and unless otherwise specified, more specifically refer to a temperature T≈293 K to 298 K (20 to 25 °C) and to a pressure P≈1 atm (101.325 kPa). These values represent standard atmospheric pressure at sea level and a typical indoor temperature range.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.”

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

As used herein, although the terms first, second, third, etc. may be used herein to describe various elements or components, these elements or components should not be limited by these terms. These terms are only used to distinguish one element or component from another element or component. Thus, a first element or component discussed below could be termed a second element or component without departing from the teachings of the inventive concept.

Unless otherwise noted, when an element or component is said to be “connected to,” “coupled to,” or “adjacent to” another element or component, it will be understood that the element or component can be directly connected or coupled to the other element or component, or intervening elements or components may be present. That is, these and similar terms encompass cases where one or more intermediate elements or components may be employed to connect two elements or components. However, when an element or component is said to be “directly connected” to another element or component, this encompasses only cases where the two elements or components are connected to each other without any intermediate or intervening elements or components.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

It should also be understood that, unless clearly indicated to the contrary, in any methods claimed herein that include more than one step or act, the order of the steps or acts of the method is not necessarily limited to the order in which the steps or acts of the method are recited.

Other implementations are within the scope of the following claims and other claims to which the applicant can be entitled.

While several inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Any combination of two or more such features, if such features are not mutually inconsistent, is included within the inventive scope of the present disclosure.

What is claimed is:

1. A resonant anti-shielding (RAS)-enhanced superconductor comprising a stacked arrangement of: (i) at least one superconducting layer formed from a superconducting material, and (ii) one or more dielectric layers formed from a point-dipole crystal or metal-organic framework material;
wherein the point-dipole crystal or metal-organic framework material comprises a plurality of polarizable units, the point-dipole crystal or metal-organic framework material forming a crystal lattice with a unit cell having a lattice period d;
wherein each of the one or more dielectric layers have a thickness a;
wherein the superconducting material has a superconducting coherence length (ξ); and
wherein the thickness a of each of the one or more dielectric layers is no greater than the lattice period d of the point-dipole crystal or metal-organic framework material, and the superconducting coherence length ( [symbol] ) of the superconducting material is at least 3 times the lattice period d of the point-dipole crystal or metal-organic framework material.

2. The RAS-enhanced superconductor of claim 1, wherein the one or more dielectric layers are formed from a metal-organic framework material and the plurality of polarizable units are periodically distributed in an organic matrix.

3. The RAS-enhanced superconductor of claim 2, wherein the organic matrix of the metal-organic framework material is planar/two-dimensional.

4. The RAS-enhanced superconductor of claim 1, wherein the crystal lattice formed from the point-dipole crystal or metal-organic framework has a two-dimensional and/or square configuration.

5. The RAS-enhanced superconductor of claim 1, wherein the point-dipole crystal or metal-organic framework material has a resonance peak at a frequency ω that coincides in frequency space with a peak or peaks in the Eliashberg function of the superconducting material.

6. The RAS-enhanced superconductor of claim 1, wherein the point-dipole crystal or metal-organic framework material has a dielectric function that is q-independent, i.e., ε_{MOF}(ω, q)=ε_{MOF}(ω).

7. The RAS-enhanced superconductor of claim 1, wherein the plurality of polarizable units of the point-dipole crystal or metal-organic framework material have phonon modes that are highly localized.

8. The RAS-enhanced superconductor of claim 1, wherein each polarizable unit of the plurality of polarizable units has a size a and a q on the order of 1/a>>k_{f}.

9. The RAS-enhanced superconductor of claim 1, wherein the stacked arrangement comprises alternating layers of the superconducting layer formed from the superconducting material and one of the one or more dielectric layers formed from the point-dipole crystal or metal-organic framework material.

10. The RAS-enhanced superconductor of claim 1, wherein the lattice period d of the point-dipole crystal or metal-organic framework material is about 0.35 nm.

11. The RAS-enhanced superconductor of claim 1, wherein the superconducting material has an effective thickness D of about 0.35 nm.

12. The RAS-enhanced superconductor of claim 1, wherein the stacked arrangement of the at least one superconducting layer and the one or more dielectric layers is characterized by an effective dielectric function ε_{DE}(ω) given approximately by the equation:
ε_{DE}(ω)=(1−f)+fε_{MOF}(ω)
where ε_{MOF}(ω) is a q-independent dielectric function characterizing each of the one or more dielectric layers, and f is a filling parameter defined by:
$$f = \frac{d}{D + d}$$
where D is an effective thickness of each layer of the at least one superconducting layer, and d is the lattice period of the point-dipole crystal or metal-organic framework material.

13. The RAS-enhanced superconductor of claim 12, wherein the stacked arrangement of the at least one superconducting layer and the one or more dielectric layers is further characterized by an immersion relationship given approximately by the equation:
D+d≤ [symbol]
where [symbol] is the superconducting coherence length of the superconducting material.

14. The RAS-enhanced superconductor of claim 12, wherein the filling parameter f is at most 0.5.

15. The RAS-enhanced superconductor of claim 1, wherein the RAS-enhanced superconductor has a superconducting critical temperature (T_{c}) at or above ambient room temperature and pressure.

16. The RAS-enhanced superconductor of claim 1, wherein the RAS-enhanced superconductor has a superconducting critical temperature (T_{c}) that is at least four times (4×) a superconducting critical temperature (
$${T}_{c}^{SC}$$
) of the superconducting material alone.

17. A method of enhancing performance of a superconductor by providing a resonant anti-shielding (RAS) effect, the method comprising:
providing at least one superconducting layer formed from a superconducting material, wherein the superconducting material has a superconducting coherence length ( [symbol] );
providing one or more dielectric layers formed from a point-dipole crystal or metal-organic framework material, wherein the point-dipole crystal or metal-organic framework material comprises a plurality of polarizable units and forms a crystal lattice with a unit cell having a lattice period d, and wherein each of the one or more dielectric layers has a thickness a; and
forming a stacked arrangement using the at least one superconducting layer and the one or more dielectric layers;
wherein the thickness a of each of the one or more dielectric layers is no greater than the lattice period d of the point-dipole crystal or metal-organic framework material, and the superconducting coherence length ( [symbol] ) of the superconducting material is at least 3 times the lattice period d of the point-dipole crystal or metal-organic framework material.

18. The method of claim 17, wherein the stacked arrangement of the at least one superconducting layer and the one or more dielectric layers is characterized by an effective dielectric function ε_{DE}(ω) given approximately by the equation:
ε_{DE}(ω)=(1−f)+fε_{MOF}(ω)
where ε_{MOF}(ω) is a q-independent dielectric function characterizing each of the one or more dielectric layers, and f is a filling parameter defined by:
$$f = \frac{d}{D + d}$$
where D is an effective thickness of each layer of the at least one superconducting layer, and d is the lattice period of the point-dipole crystal or metal-organic framework material.

19. The method of claim 18, wherein the stacked arrangement of the at least one superconducting layer and the one or more dielectric layers is further characterized by an immersion relationship given approximately by the equation:
D+d≤ [symbol]
where [symbol] is the superconducting coherence length of the superconducting material.

20. The method of claim 17, wherein the RAS-enhanced superconductor has a superconducting critical temperature (T_{c}) at or above ambient room temperature and pressure, and/or
wherein the RAS-enhanced superconductor has a superconducting critical temperature (T_{c}) that is at least four times (4×) a superconducting critical temperature
$${T}_{c}^{SC}$$
of the superconducting material alone.
